(19) United States
(12) Patent Application Publication
(10) Pub. No.: US 2002/0129770 A1
(43) Pub. Date: Sep. 19, 2002

(54) Vacuum deposition system

(76) Inventors: Koichi Okamoto, Hyogo (JP); Yoshimitsu Fukuda, Hyogo (JP)

Correspondence Address: MARSHALL, GERSTEIN & BORUN, 6300 SEARS TOWER, 233 SOUTH WACKER, CHICAGO, IL, 60606-6357, US

(21) Appl. No.: 10/099,502

(22) Filed: Mar. 15, 2002

(30) Foreign Application Priority Data
Mar. 19, 2001 (JP) 2001-078281

(51) Int. Cl. C23C 16/00; B05C 11/00

(52) U.S. Cl. 118/723 EB; 118/728; 118/712; 118/726

(57) ABSTRACT

A vacuum deposition system comprising a vacuum chamber used for keeping a vacuum atmosphere within an inner space thereof for film deposition and an auxiliary device used in the vacuum chamber for assisting film deposition, wherein the auxiliary device is mounted so as to extend in the outside and inside of the vacuum chamber through an opening defined in the vacuum chamber such that the auxiliary device is secured to a stationary structural member disposed outside the vacuum chamber while being attached to the vacuum chamber by a connection member having elasticity and formed from a material capable of maintaining the vacuum atmosphere within the vacuum chamber.

### BACKGROUND OF THE INVENTION

1. Field of the Invention

The present invention relates to a vacuum deposition system.

2. Description of the Related Art

In a typical vacuum deposition system, an evaporation source is provided in a vacuum chamber and film deposition is carried out in such a way that film material which has been evaporated by the evaporation source is sprinkled in the form of a film over the surface of a substrate held in the vacuum chamber. Within the inner space of the vacuum chamber in which the evaporation source is disposed and the substrate is held, a vacuum atmosphere having a specified pressure is established by an evacuating means such as vacuum pumps to evaporate the film material so as to be deposited on the surface of the substrate.

The substrate on which the film is deposited is supported by a substrate holder attached to the vacuum chamber. The substrate holder is, in turn, attached to the vacuum chamber through an opening called a port provided for the vacuum chamber, so that the substrate can be supported by the substrate holder within the inner space of the vacuum chamber.

In addition to the evaporation source and the substrate holder, the vacuum chamber further comprises a variety of auxiliary devices used for film deposition carried out within the vacuum chamber, examples of such auxiliary devices including an optical monitor (thickness sensor) for optically detecting the thickness of the film deposited on the substrate; a thickness adjuster board for adjusting the thickness of the film (hereinafter referred to as “correcting board”); and a temperature sensor for detecting the temperature of the substrate during film deposition.

It should be noted that the optical monitor is used for determining whether or not satisfactory film deposition has been done to attain a target film, through the procedure in which an optical monitor light projector section projects light onto the substrate and an optical monitor light receiving section detects the light which has passed through the substrate or has been reflected from the substrate, thereby to measure the thickness of the film formed on the substrate.

When the air within the inner space of the vacuum chamber is exhausted by the evacuating means to decrease pressure, the pressure within the vacuum chamber becomes different from the pressure outside the vacuum chamber, which sometimes causes distortion of the vacuum chamber.

If distortion of the vacuum chamber occurs, the relative positions of the substrate holder attached to the vacuum chamber, the optical monitor light projector section and the optical monitor light receiving section deviate from their proper relationship, causing a shift of the optical axis of the optical monitor, so that the measurement of the film by the optical monitor cannot be made with high accuracy.

Similarly, if the vacuum chamber is distorted, the evaporation source, correcting board, temperature sensor and others cannot maintain a proper positional relationship with respect to the substrate. If a relative shift between the evaporation source and the substrate occurs, the thickness distribution of the film material which has been evaporated by the evaporation source will vary. Similarly, if a relative shift between the correcting board and the substrate occurs, difficulties arise in ensuring the uniformity of film thickness. If a relative shift between the temperature sensor and the substrate occurs, it becomes impossible to accurately measure the temperature of the substrate which is one of the important conditions for film deposition.

Such relative shifts of a variety of auxiliary devices due to distortion of the vacuum chamber thus cause various troubles in film deposition and could be an obstacle to the achievement of high-accuracy film deposition.

As one attempt to overcome the above problems, the conventional vacuum deposition system is designed to prevent the distortion of the vacuum chamber by specially thickening the chamber wall or providing special reinforcements in the positions of the vacuum chamber where the substrate holder, the optical monitor light projector section, the optical monitor light receiving section and other auxiliary devices are mounted.

The provision of the above special arrangement for the vacuum chamber, however, has proved unsuccessful because it involves a complexity in the structure of the vacuum chamber, an increased size of the vacuum chamber and, in consequence, poor manufacturing cost performance of the film deposition system.

### SUMMARY OF THE INVENTION

A primary object of the invention is accordingly to provide a vacuum deposition system which does not cause problems due to distortion of the vacuum chamber such as decreased accuracy in measurements of a film by the optical monitor and does not involve a complexity in the structure of the vacuum chamber.

The invention has been made taking the above background into account and therefore provides a vacuum deposition system comprising a vacuum chamber used for keeping a vacuum atmosphere within an inner space thereof for film deposition and an auxiliary device used in the vacuum chamber for assisting film deposition, wherein the auxiliary device is mounted so as to extend in the outside and inside of the vacuum chamber through an opening defined in the vacuum chamber such that the auxiliary device is secured to a stationary structural member disposed outside the vacuum chamber while being attached to the vacuum chamber by a connection member having elasticity and formed from a material capable of maintaining the vacuum atmosphere within the vacuum chamber.

By virtue of this arrangement, film deposition by use of the auxiliary device such as a thickness sensor, thickness adjuster board, evaporation source or temperature sensor can be carried out with high accuracy, because even if the vacuum chamber is distorted, the displacement, which is caused by the distortion and would affect the absolute position (e.g., the position with respect to the stationary structural member) of the auxiliary device, is absorbed by the connection member so that the absolute position of the auxiliary device is not changed.

According to the invention, the connection member is a bellows and disposed so as to provide sealing between the auxiliary device and the opening.

Use of a bellows as the connection member makes it possible to simplify the structure for connection between the auxiliary device and the vacuum chamber and to reliably maintain the vacuum atmosphere within the vacuum chamber.

According to the invention, the auxiliary device is one or more devices selected from the group consisting of a substrate holder, thickness sensor for detecting the thickness of a film, thickness adjuster board for adjusting the thickness of the film, evaporation source for evaporating the material of the film, and temperature sensor for detecting the temperature of a substrate on which the film is deposited.

By use of one or more devices selected from the group consisting of a substrate holder, thickness sensor, thickness adjuster board (correcting board), evaporation source and temperature sensor as the auxiliary device, the following advantages can be achieved: for instance, in cases where an optical monitor is used as a thickness sensor, relative shifts of the substrate holder, the optical monitor light projector section and the optical monitor light receiving section do not occur, so that measurements of film thickness can be made with high accuracy. In addition, a relative shift between the substrate holder and the evaporation source does not occur, resulting in a uniform thickness distribution of the deposited film. Similarly, a relative shift between the substrate holder and the correcting board does not occur so that uniform film thickness can be ensured. Also, a relative shift between the substrate holder and the temperature sensor can be eliminated to accurately measure the temperature of the substrate which is one of the conditions for film deposition. On the whole, no displacement occurs in the absolute positions of various auxiliary devices so that film deposition can be carried out more accurately than ever before.

According to the invention, there is provided a vacuum deposition system comprising: a vacuum chamber having a vacuum atmosphere within an inner space thereof; an evaporation source for evaporating a film material placed in the vacuum chamber; a substrate holder for supporting a substrate, on a surface of which a film is to be formed, in the inner space of the vacuum chamber through an opening defined in the vacuum chamber, in such a manner the surface of the substrate faces the center of the vacuum chamber; an optical monitor light projector section secured to a stationary structural member disposed outside the vacuum chamber, for projecting light onto the substrate from the outside of the vacuum chamber; and an optical monitor light receiving section secured to the stationary structural member disposed outside the vacuum chamber, for receiving light from the substrate; wherein the substrate holder is secured to the stationary structural member disposed outside the vacuum chamber while being attached to the vacuum chamber through buffer means which has elasticity and is formed from a material capable of maintaining the vacuum atmosphere within the vacuum chamber.

With this arrangement, the substrate holder is securely supported by the stationary structural member positioned outside the vacuum chamber and attached to the vacuum chamber through the buffer means. Accordingly, the possible displacement of the vacuum chamber caused by its distortion is absorbed by the buffer means so that the position of the substrate holder is not changed by the possible displacement of the vacuum chamber due to distortion.

Not only the substrate holder but also the optical monitor light projector section and the optical monitor light receiving section are securely supported by the stationary structural member positioned outside the vacuum chamber so that relative shifts between these members and, therefore, a shift of the optical axis of light for detecting the thickness of the film on the substrate do not occur. This enables high accuracy detection of the thickness of the film formed on the substrate by use of the optical monitor.

In the vacuum deposition system of the invention, the optical monitor light receiving section is integrally incorporated into a casing for covering the substrate holder and located on the side of a back face of the substrate supported by the substrate holder, the back face being opposite to the surface of the substrate, and the optical monitor light projector section and the optical monitor light receiving section face each other across the center of the vacuum chamber.

According to the above arrangement, the optical monitor light receiving section is integrally incorporated into the substrate holder and outgoing light from the optical monitor light projector section, which is placed so as to face the optical monitor light receiving section, is detected on the side of the back face of the substrate to detect the thickness of the film formed on the substrate. Therefore, accurate film thickness detection can be achieved and the structure for installation of the optical monitor within the vacuum chamber can be simplified.

In the above vacuum deposition system, the buffer means is a bellows and the substrate holder is securely attached to the stationary structural member disposed outside the vacuum chamber together with one end of the bellows while the other end of the bellows being attached to the peripheral edge of the opening of the vacuum chamber.

Use of a bellows as the buffer means makes it possible to simplify the structure for attaching the substrate holder to the vacuum chamber.

### BRIEF DESCRIPTION OF DRAWINGS

FIG. 1 is a front sectional view of a vacuum deposition system constructed according to the invention.

FIG. 2 is a partially enlarged view showing an upper portion of the vacuum deposition system shown in FIG. 1.

FIG. 3 is a partial sectional view showing another arrangement for preventing a shift of an evaporation source owing to distortion of a vacuum chamber.

### DETAILED DESCRIPTION OF PREFERRED EMBODIMENTS

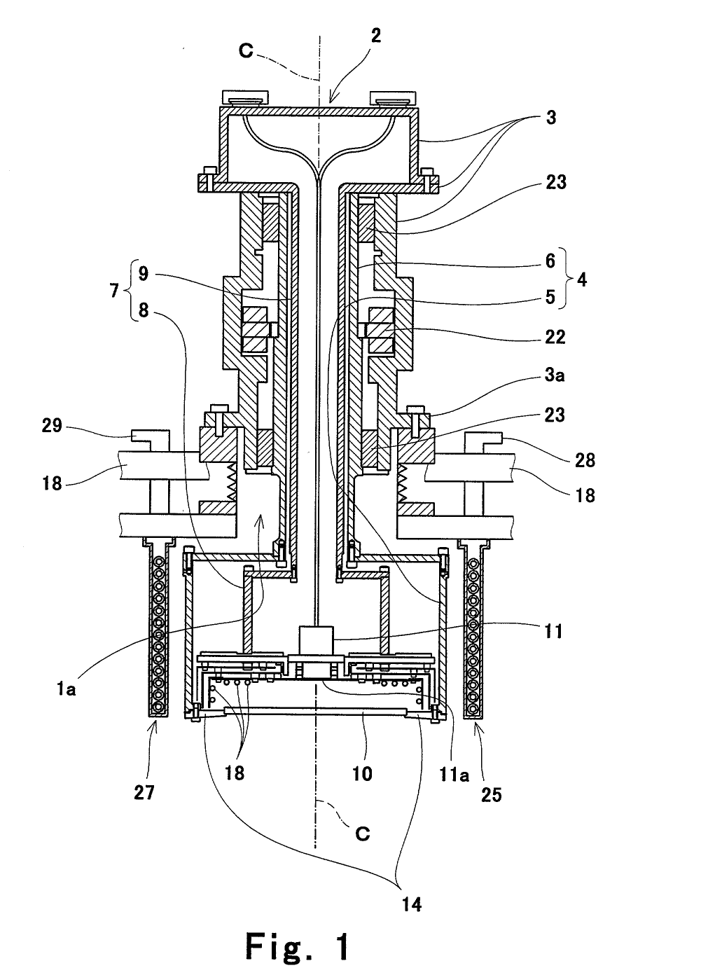

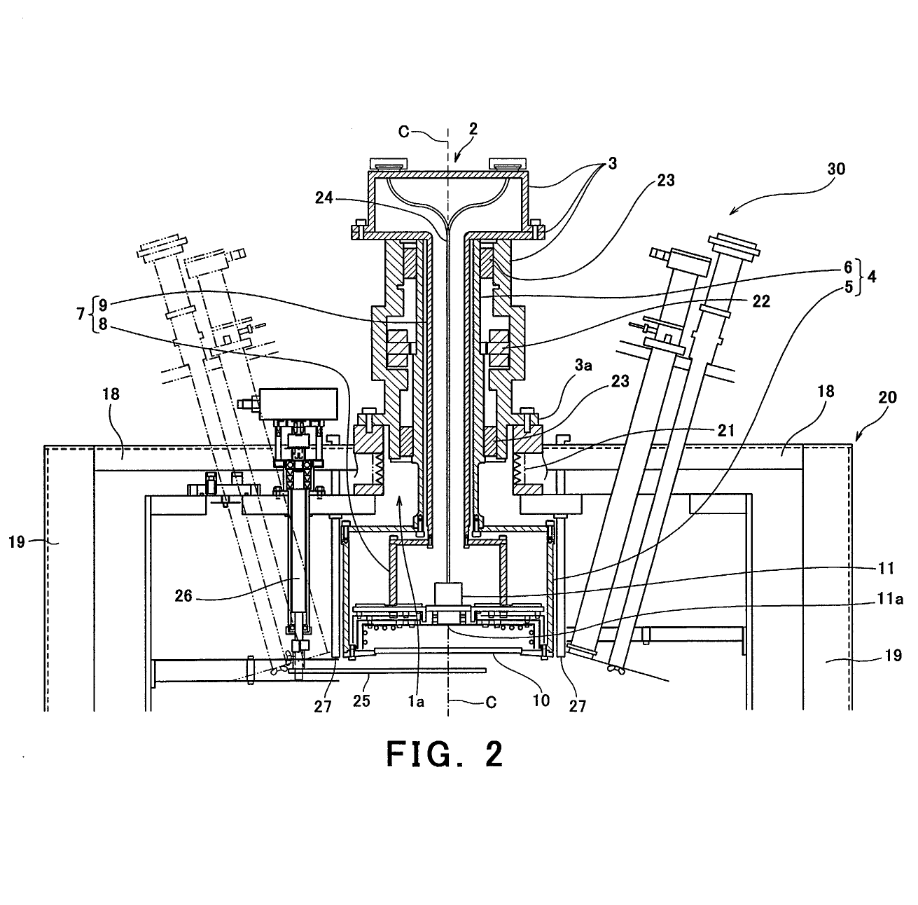

Referring now to FIGS. 1 and 2, preferred embodiments of the invention will be described below.

FIG. 1 diagrammatically shows a structure of a vacuum film deposition system 30 according to one embodiment of the invention and a front elevation of the film deposition system 30. FIG. 2 shows a partially enlarged view of an upper portion of the film deposition system 30 shown in FIG. 1.

The film deposition system 30 shown in FIGS. 1 and 2 is constructed to deposit a film on a substrate 10 placed within a vacuum chamber 1 by the so-called vacuum deposition that is one of film deposition techniques. The vacuum chamber 1 is designed such that its inner space is evacuated with the aid of a vacuum pump (not particularly shown) so as to have a desired vacuum atmosphere.

Disposed at the lower part of the chamber 1 are two evaporation sources 14 for evaporating film material within the inner space of the chamber 1. The evaporation sources 14 each have a crucible 14a and an electron gun for projecting electron beams to the film material for heating.

The film deposition system 30 is provided with shielding boards 15 positioned above the respective evaporation sources 14 for shielding the evaporation sources 14. Each shielding board 15 is actuated so as to rotate around a post 13. Where electron beams are projected to heat the film material, a certain period of time is required for stable evaporating the film material. Therefore, if the film material is heated by the evaporation sources 14 to form a film so as not to be adhered to a substrate 10, the shielding boards 15 are respectively actuated to be positioned above the evaporation sources 14 to cover them. On the other hand, if the film material is evaporated by the evaporation sources 14 to form a film so as to be adhered to the substrate 10, the shielding boards are actuated to be retracted from their associated positions just above the evaporation sources 14.

In the upper inner part of the vacuum chamber 1, the substrate 10 is supported by a substrate rotating mechanism 2 having a substrate holder at the lower part thereof. The substrate rotating mechanism 2 is fitted in an opening (port) 1a that is defined in the vacuum chamber 1 for accommodating the substrate rotating mechanism 2. The substrate rotating mechanism 2 includes a casing 3, a substrate support 4 and a sensor support 7. The casing 3 encloses the outside of the substrate rotating mechanism 2 and is rotationally symmetrical about a central axis C.

The substrate support 4 includes a substrate mounting section 5 and a cylindrical sheath 6 for supporting the substrate mounting section 5 at its lower end. The substrate mounting section 5 is so formed as to be rotationally symmetrical about a central axis C and supported by the lower end of the hollow cylindrical sheath 6 which is also rotationally symmetrical about a central axis C, such that their central axes C are coincident with each other. Since the cylindrical sheath 6 extends into the vacuum chamber 1 from outside through the opening 1a defined in the vacuum chamber 1, its lower end by which the substrate mounting section 5 is supported is positioned inside the vacuum chamber 1. The substrate 10 is attached to the lower part of the substrate mounting section 5 such that the surface of the substrate 10, on which the film is to be formed, faces the center of the chamber 1 (i.e., downwardly).

The cylindrical sheath 6 is disposed with its periphery in sliding contact with an actuating section of a direct drive motor 22 and is actuated by the direct drive motor 22 so as to rotate about the central axis C together with the substrate mounting section 5. This enables film deposition while the substrate 10 being rotated.

Since the substrate mounting section 5 and the cylindrical sheath 6 support the substrate 10 as described earlier, the substrate rotating mechanism 2 is attached to the outside of the vacuum chamber 1, while projecting into the chamber 1 through the opening 1a to support the substrate 10 within the inner space of the vacuum chamber 1.

Disposed between the cylindrical sheath 6 and the casing 3 are a plurality of magnetic fluid seals 23 which are arranged in a longitudinal direction of the cylindrical sheath 6 such that the vacuum condition within the chamber 1 can be maintained.

The sensor support 7 includes a sensor mounting section 8 and a cylindrical portion 9, the sensor mounting section 8 being attached to the lower end of the cylindrical portion 9. The cylindrical portion 9 is positioned inside the cylindrical sheath 6 and the sensor mounting section 8 inside the substrate mounting section 5. The cylindrical portion 9 is so formed as to be rotationally symmetrical about the central axis C and hollowed. The upper part of the casing 3 is partially constituted by a portion, which is formed integrally with the cylindrical portion 9, so as to laterally extend from the upper end of the cylindrical portion 9.

Attached to the lower end of the sensor mounting section 8 is an optical monitor light receiving section 11 with a light receiving head 11a facing downward. As a result, the optical monitor light receiving section 11 is located above the substrate 10 when viewed from the center of the vacuum chamber 1, whereas the light receiving head 11a is opposed to the back face of the substrate 10.

Light going out of an optical monitor light projector section 12 (to be described later) passes through the substrate 10 and is then received by the optical monitor light receiving section 11, whereby an optical signal is generated. The optical signal detected by the optical monitor light receiving section 11 includes data associated with the thickness of the film formed on the substrate 10 so that the thickness of the film on the substrate 10 can be detected by detection of the optical signal.

The optical signal detected by the optical monitor light receiving section 11 is guided outward as an electric signal via a signal line 24 provided in the cylindrical portion 9 and then input to a controller (not shown) provided for the film deposition system 30. This controller detects the thickness of the film deposited by the film deposition system 30.

It should be noted that the sensor support 7 is fixed to the casing 3 of the substrate rotating mechanism 2 and is assembled, in view of the structure, separately from the substrate support 4 that rotates outside the sensor support 7.

The optical monitor light projector section 12 projects light from a light projector head 12a, the light having a wavelength detectable by the optical monitor light receiving section 11. In the case of the film deposition system 30, the optical monitor light projector section 12 is located outside the vacuum chamber 1 and the light projector head 12a is opposed to the light receiving head 11a of the optical monitor light receiving section 11 with the center of the vacuum chamber 1 between.

Specifically, in the film deposition system 30, the optical monitor light projector section 12 is arranged so as to project light into the chamber 1 through a port 1b opposite to the port 1a in which the substrate rotating mechanism 2 is mounted relative to the center of the vacuum chamber 1. The port in which the optical monitor light projector section 12 is mounted is provided with a window that is optically transparent with respect to the light emitted from the optical monitor light projector section 12 so that the light from the optical monitor light projector section 12 is guided into the vacuum chamber 1.

The film material evaporated by the evaporation sources 14 is so dispersed as to form a distribution dependent of the distance from the electron beam irradiating position of the film material. For film deposition, the substrate 10 is therefore rotated about the central axis C by actuating the direct drive motor 22 as described earlier in order to obtain more uniform film thickness. However, it has been found that film thickness is at its maximum value at the center of the rotating substrate 10 and tends to decrease as the measuring position is away from the center in a radial direction. To eliminate the variation of film thickness, the present embodiment employs a correcting board 25. The correcting board 25 has an elongated sheet shape and is disposed in parallel with the substrate 10, being located in the vicinity of the substrate 10 and between the substrate 10 and the evaporation sources 14. The correcting board 25 is arranged such that one of the lengthwise ends is positioned at the center of rotation of the rotating substrate 10 whereas the other end is supported by the vacuum chamber 1 and a substrate rotating mechanism counter 18 through a bar-like correcting board support shaft 26.

In the film deposition system 30 of the present embodiment, the substrate rotating mechanism 2 is provided with a heater (not shown) for controlling the temperature of the substrate 10 which is one of the conditions for film deposition. The power line for supplying power to the heater is provided in the cylindrical portion 9 which constitutes the sensor support 7 and connected to an external power source. There is provided a thermocouple (not shown) as a temperature sensor for detecting the temperature of the substrate 10 heated by the heater. The thermocouple is disposed within the cylindrical portion 9 similarly to the power line of the heater, with its hot junction being in close contact with the surface of the substrate 10 while its cold junction is positioned outside the substrate rotating mechanism 2.

A cooling section 27 in cylindrical form is disposed so as to enclose the substrate mounting section 5 with one of its opening ends being attached to the ceiling of the chamber 1. The cooling section 27 adsorbs heat radiated from the heater and restrains the magnetic fluid seals 23 from being heated, so that the airtightness of the chamber 1 established by the magnetic fluid seals 23 is prevented from being lost.

As described earlier, the film deposition system 30 of the present embodiment is designed such that the optical monitor light receiving section 11 is integrally incorporated into the substrate rotating mechanism 2 and film thickness is detected by the optical monitor light receiving section 11 disposed on the side of the back face of the substrate 10. This enables accurate film thickness detection and simplifies the structure for mounting the optical monitor light receiving section 11 in the vacuum chamber 1.

The film deposition system 30 is supported by an installation counter 20 that is a stationary structural member disposed outside the vacuum chamber 1. The installation counter 20 includes a chamber counter 16, an optical monitor light projector section counter 17, the substrate rotating mechanism counter 18 and a vertical frame 19 and is constructed by assembling these members. The installation counter 20 is securely supported on a floor of the like in a laboratory where the film deposition system 30 is installed.

The chamber counter 16 is horizontally disposed along the lower end of the vacuum chamber 1, supporting the vacuum chamber 1 from its underside. The optical monitor light projector section counter 17 is horizontally disposed under the chamber counter 16 to support the optical monitor light projector section 12 from its underside. The substrate rotating mechanism counter 18 is horizontally disposed above the vacuum chamber 1 to support the substrate rotating mechanism 2 from its underside. The vertical frame 19 vertically extends beside the substrate rotating mechanism counter 18, the chamber counter 16 and the optical monitor light projector section counter 17, so as to couple these counters 16, 17, 18.

The installation counter 20 comprised of the chamber counter 16, the optical monitor light projector section counter 17, the substrate rotating mechanism counter 18 and the vertical frame 19 has a rigid structure capable of supporting the vacuum chamber 1, the substrate rotating mechanism 2 and others which have significant weight.

The substrate rotating mechanism 2 is attached to the substrate rotating mechanism counter 18 and to the vacuum chamber 1 through a bellows 21 that serves as a buffer means (connecting member). More specifically, the substrate rotating mechanism 2 is mounted in the following fashion.

The substrate rotating mechanism 2 is attached to the substrate rotating mechanism counter 18 at its mounting flange 3a together with a lengthwise end of the bellows 21. This allows the substrate rotating mechanism 2 to be fixedly supported by the substrate rotating mechanism counter 18.

The other lengthwise end of the bellows 21 is attached to the peripheral edge of the opening 1a of the vacuum chamber 1. Thus, the substrate rotating mechanism 2 is attached to the vacuum chamber 1 through the bellows 21.

The bellows 21 is made from a metallic material and is an elastic structural member in the form of a cylinder having a bellows-like side wall. The bellows 21 is designed to be expandable and contractible with both opening ends moving in an axial direction and to be deformable in such a way that one of the opening ends is shifted relative to the other in a direction perpendicular to the axis of the bellows 21.

The bellows 21 is made from a material having enough strength to withstand the difference in pressure between the inside and outside of the vacuum chamber 1 so that it can maintain the vacuum condition within the vacuum chamber 1.

According to such a film deposition system 30, since the substrate rotating mechanism 2 into which the optical monitor light receiving section 11 is integrally incorporated and the optical monitor light projector section 12 are mounted on the installation counter 20 that is a stationary structural member, relative shifts between the optical monitor light projector section 12, the optical monitor light receiving section 11 and the substrate 10 do not occur.

Even if the vacuum chamber 1 is mechanically distorted when the vacuum chamber 1 is evacuated by the vacuum pump or the like and therefore the pressure within the chamber 1 is lowered, the displacement of the chamber 1 subsequent to the distortion can be adsorbed by the bellows 21 and in consequence, an undesirable situation (e.g., displacement) does not occur in the substrate rotating mechanism 2 under the influence of the distortion of the chamber 1.

In addition, since the film deposition system 30 of the present embodiment is designed such that the heater, power line, and thermocouple (serving as a temperature sensor) are disposed within the substrate rotating mechanism 2 as described earlier, relative shifts between these auxiliary devices and the substrate 10 do not occur similarly to the case of the optical monitor light receiving section 11.

While the invention has been particularly described with a case where shifts of the substrate rotating mechanism 2 having a substrate holder and the optical monitor light projector section 12 are prevented, the shifts being attributable to distortion of the vacuum chamber 1, it is readily apparent that the invention may be applied to other auxiliary devices.

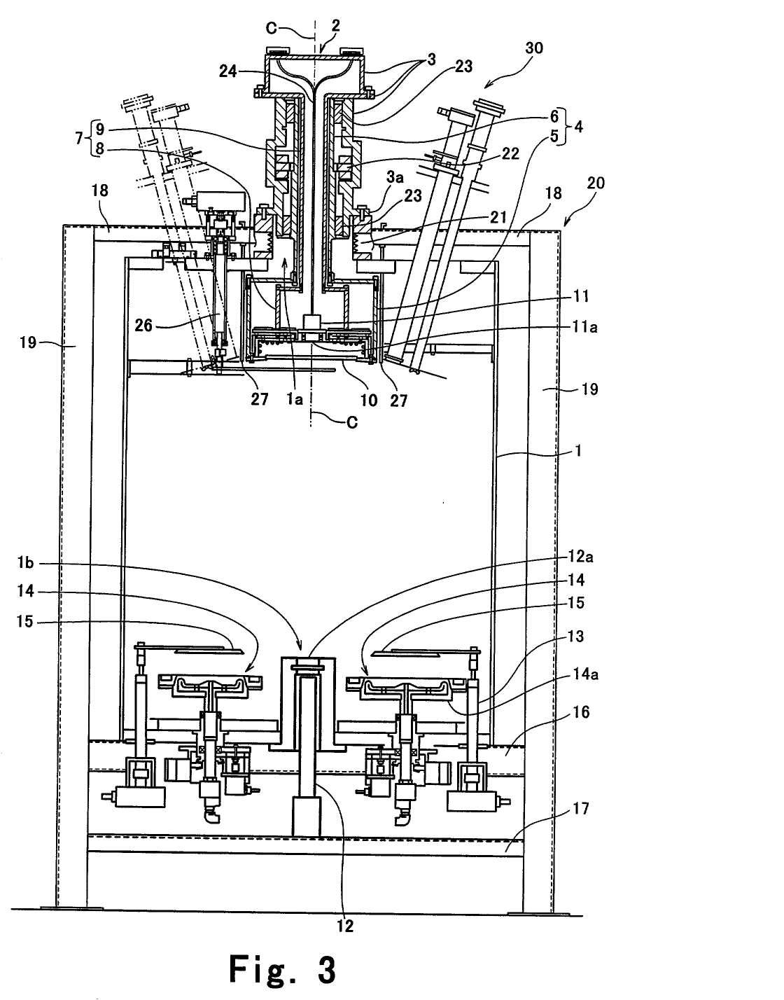

For example, FIG. 3 shows a partial sectional view of another embodiment of the invention which pertains to a structure for preventing a shift of an evaporation source 14 attributable to distortion of the vacuum chamber 1. As illustrated in FIG. 3, the evaporation source 14 is attached to the vacuum chamber 1 and to the chamber counter 16 through a bellows 14c.

More concretely, the evaporation source 14 is composed of a crucible 14a on which film material is to be placed and a rotating shaft 14b for supporting the crucible 14a at its upper part and transmitting a rotary driving force generated by a motor M to the crucible 14a. Disposed on the chamber counter 16 is a cylindrical bearing member 14d having a disk-like flange 14e joined to its lower end. The axis of the bearing member 14d extends vertically. The bearing member 14d extends into the vacuum chamber 1 through an opening 1c defined in the vacuum chamber 1 so that the upper part of the bearing member 14d is positioned within the vacuum chamber 1.

The flange 14e has an aperture having the same diameter as the inner diameter of the bearing member 14d. The rotating shaft 14b penetrates through the bearing member 14d and the flange 14e and pierces into the chamber counter 16. The motor M is connected to the lower part of the rotating shaft 14b.

One opening end of the bellows 14c is attached to the chamber counter 16 together with the flange 14e whereas the other opening end is attached to the peripheral edge of the opening 1c of the vacuum chamber 1.

With this arrangement, the evaporation source 14 is securely attached to the chamber counter 16 together with the one opening end of the bellows 14c and even if the vacuum chamber 1 is distorted, the displacement which would affect the evaporation source 14 is adsorbed by the bellows 14c. Since the space between the vacuum chamber 1 and the chamber installation counter 16 is sealed with the bellows 14c, the vacuum atmosphere within the vacuum chamber 1 can be maintained.

Additionally, the effect of adsorbing displacement which causes a relative shift between the substrate 10 and the correcting board 25 in the event of distortion of the vacuum chamber 1 can be achieved by forming the correcting board 25 by use of a bellows in the similar fashion. In cases where the heater, the power line and the thermocouple are not integral with the substrate rotating mechanism 2 but separately formed so as to extend into the vacuum chamber 1 through the opening defined therein, the same effect can be attained by the similar arrangement using a bellows.

Specifically, among auxiliary devices used in the vacuum film deposition system 30, those that extend through the opening of the vacuum chamber 1 to be positioned within the vacuum chamber 1 can be all free from the influence of distortion of the vacuum chamber 1, by forming them in the same structure as the substrate rotating mechanism 2 or the evaporation systems 14 by use of a bellows, so that high-accuracy film deposition can be ensured.

While the foregoing discussion has been presented in terms of the buffer means constituted by a bellows, other structural members may be used provided that they have elasticity and enough strength to withstand the difference in pressure between the internal space leading to the inside of the vacuum chamber 1 and the external space exposed to atmospheric pressure. In addition, since the substrate rotating mechanism is installed in the vacuum chamber through the buffer means, the structural member employed as the buffer means is desirably designed such that one opening end can be fixed to the installation counter together with the substrate rotating mechanism while the other opening end being attached to the opening portion of the vacuum chamber.

Although the film deposition system 30 explained in the foregoing description is formed such that the optical monitor light projector section 12 and the optical monitor light receiving section 11 are opposed to each other across the center of the chamber 1, they are not necessarily opposed to each other with respect to the center of the chamber 1.

Concretely, although it is required that the optical monitor light projector section and the optical monitor light receiving section be securely supported by the stationary structural member positioned outside the chamber 1, they are not necessarily opposed to each other with respect to the center of the chamber 1. In an alternative arrangement, the optical monitor light projector section and the optical monitor light receiving section may be both installed on the side of the back face of the substrate and light reflected from the substrate may be received on the side of the back face of the substrate to detect the thickness of the film formed on the surface of the substrate.

It should be noted that wherever the optical monitor light projector section and the optical monitor light receiving section, which are fixed to the stationary structural member disposed outside the chamber 1, are disposed, the substrate rotating system for supporting the substrate can be securely supported by the stationary structural member outside the chamber 1, while being installed in the vacuum chamber 1 through the buffer means. With this arrangement, the substrate holder can be installed in the vacuum chamber and displacement or the like of the substrate holder and the substrate rotating mechanism due to distortion of the vacuum chamber can be prevented.

Although the film deposition system 30 set forth in the foregoing description is a vacuum deposition system for forming a film by vacuum deposition, it is apparent that the invention is applicable to systems in which other deposition techniques are employed.

For instance, the invention may be applied to a film deposition system employing ion-plating etc. for film deposition on condition that a substrate holder for supporting a substrate is fixedly supported by a stationary structural member positioned outside a vacuum chamber while being placed in the vacuum chamber through a buffer means and that an optical monitor light projector section and an optical monitor light receiving section, which are used for detecting the thickness of a film to be formed on the substrate, are securely supported by the stationary structural member.

Accordingly, the invention provides a vacuum deposition system which is free from film deposition troubles due to distortion of the vacuum chamber and does not give rise to a need for a large-sized vacuum chamber and drawbacks such as a complexity in the structure of the vacuum chamber.

What is claimed is:

1. A vacuum deposition system comprising a vacuum chamber used for keeping a vacuum atmosphere within an inner space thereof for film deposition and an auxiliary device used in the vacuum chamber for assisting film deposition,
wherein the auxiliary device is mounted so as to extend in the outside and inside of the vacuum chamber through an opening defined in the vacuum chamber such that the auxiliary device is secured to a stationary structural member disposed outside the vacuum chamber while being attached to the vacuum chamber by a connection member having elasticity and formed from a material capable of maintaining the vacuum atmosphere within the vacuum chamber.

2. The vacuum deposition system according to claim 1, wherein the connection member is a bellows and disposed so as to provide sealing between the auxiliary device and the opening.

3. The vacuum deposition system according to claim 1, wherein the auxiliary device is one or more devices selected from the group consisting of a substrate holder; thickness sensor for detecting the thickness of a film; thickness adjuster board for adjusting the thickness of the film; evaporation source for evaporating the material of the film; and temperature sensor for detecting the temperature of a substrate on which the film is deposited.

4. The vacuum deposition system according to claim 2, wherein the auxiliary device is one or more devices selected from the group consisting of a substrate holder; thickness sensor for detecting the thickness of a film; thickness adjuster board for adjusting the thickness of the film; evaporation source for evaporating the material of the film; and temperature sensor for detecting the temperature of a substrate on which the film is deposited.

5. A vacuum deposition system comprising:
a vacuum chamber having a vacuum atmosphere within an inner space thereof;
an evaporation source for evaporating a film material placed in the vacuum chamber;
a substrate holder for supporting a substrate, on a surface of which a film is to be formed, in the inner space of the vacuum chamber through an opening defined in the vacuum chamber, in such a manner said surface of the substrate faces the center of the vacuum chamber;
an optical monitor light projector section secured to a stationary structural member disposed outside the vacuum chamber, for projecting light onto the substrate from the outside of the vacuum chamber; and
an optical monitor light receiving section secured to the stationary structural member disposed outside the vacuum chamber, for receiving light from the substrate;
wherein the substrate holder is secured to the stationary structural member disposed outside the vacuum chamber while being attached to the vacuum chamber through buffer means which has elasticity and is formed from a material capable of maintaining the vacuum atmosphere within the vacuum chamber.

6. The vacuum deposition system according to claim 5,
wherein the optical monitor light receiving section is integrally incorporated into a casing for covering the substrate holder and located on the side of a back face of the substrate supported by the substrate holder, said back face being opposite to said surface of the substrate, and
wherein the optical monitor light projector section and the optical monitor light receiving section face each other across the center of the vacuum chamber.

7. The vacuum deposition system according to claim 5,
wherein the buffer means is a bellows and
wherein the substrate holder is securely attached to the stationary structural member disposed outside the vacuum chamber together with one end of the bellows while the other end of the bellows being attached to the peripheral edge of the opening of the vacuum chamber.

8. The vacuum deposition system according to claim 6,
wherein the buffer means is a bellows and
wherein the substrate holder is securely attached to the stationary structural member disposed outside the vacuum chamber together with one end of the bellows while the other end of the bellows being attached to the peripheral edge of the opening of the vacuum chamber.
